(19) United States
(12) Patent Application Publication
(10) Pub. No.: US 2021/0371627 A1
(43) Pub. Date: Dec. 2, 2021

(54) RESIN COMPOSITION AND ARTICLE MADE THEREFROM

(71) Applicant: Elite Material Co., Ltd., Taoyuan City (TW)

(72) Inventors: Kok-Sheng TAN, Taoyuan City (TW); Ching-Hsien HSU, Taoyuan City (TW)

(21) Appl. No.: 16/923,283

(22) Filed: Jul. 8, 2020

(30) Foreign Application Priority Data
May 26, 2020 (TW) 109117408

(51) Int. Cl. C08L 9/00; C08J 5/24

(52) U.S. Cl. CPC C08L 9/00; C08J 5/24; C08L 2207/53; C08J 2479/08; C08L 2201/02; C08J 2309/00; C08L 2205/03

(57) ABSTRACT

A resin composition includes 100 parts by weight of a polybutadiene and 10 parts by weight to 40 parts by weight of a maleimide resin, wherein: the polybutadiene has a 1,2-vinyl content of greater than or equal to 85%; the polybutadiene has a lithium ion content of less than or equal to 100 ppm; and the resin composition is free from a polyphenylene ether resin. Moreover, an article may be made from the resin composition, including a prepreg, a resin film, a laminate or a printed circuit board.

### CROSS-REFERENCE TO RELATED APPLICATION

This application claims the priority benefits of Taiwan Patent Application No. 109117408, filed on May 26, 2020. The entirety the above-mentioned patent application is hereby incorporated by reference herein and made a part of this specification.

### BACKGROUND

### 1. Field of the Disclosure

The present disclosure relates to a resin composition and more particularly to a resin composition useful for preparing a prepreg, a resin film, a laminate or a printed circuit board.

### 2. Description of Related Art

With the rapid advancement of the fifth generation mobile communication technology (5G), resin materials suitable for data transmission at high frequency and high speed have become the mainstream of laminate development, so as to satisfy the demands of extremely low dissipation factor (a dissipation factor of less than or equal to 0.0025 at 10 GHz) even at high temperature variation and high humidity variation and at the same time possess a comparative tracking index passing the test at high voltage, so as to meet the indicators of high performance laminates.

### SUMMARY

To overcome the problems of prior arts, particularly one or more above-mentioned technical problems facing conventional materials, it is a primary object of the present disclosure to provide a resin composition and an article made therefrom which may overcome at least one of the above-mentioned technical problems.

In view of the aforesaid object, the present disclosure provides a resin composition, comprising 100 parts by weight of a polybutadiene and 10 parts by weight to 40 parts by weight of a maleimide resin, wherein: the polybutadiene has a 1,2-vinyl content of greater than or equal to 85%; the polybutadiene has a lithium ion content of less than or equal to 100 ppm; and the resin composition is free from a polyphenylene ether resin.

For example, the polybutadiene is a polymer of butadiene, such as a homopolymer of butadiene, and has a 1,2-vinyl content of greater than or equal to 85%, such as a 1,2-vinyl content of greater than or equal to 90%, such as a 1,2-vinyl content of greater than or equal to 85% and less than or equal to 95%, or such as a 1,2-vinyl content of greater than or equal to 90% and less than or equal to 95%, but not limited thereto. In addition, the polybutadiene has a lithium ion content of less than or equal to 100 ppm, such as a lithium ion content of between 1 ppm and 100 ppm or between 10 ppm and 100 ppm, but not limited thereto.

For example, in one embodiment, examples of the maleimide resin are not particularly limited and may comprise various maleimide resins known in the art to which this disclosure pertains; examples include 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, vinyl benzyl maleimide, maleimide resin containing aliphatic long chain structure, prepolymer of diallyl compound and maleimide resin, prepolymer of diamine and maleimide resin, prepolymer of multi-functional amine and maleimide resin, prepolymer of acid phenol compound and maleimide resin, or a combination thereof. Unless otherwise specified, “maleimide resin” as used herein should be construed as including the modifications thereof.

One of the main features of the resin composition is that the resin composition does not contain any polyphenylene ether resin. As used herein, the polyphenylene ether resin refers to any polyphenylene ether resins commonly used for preparing a prepreg, a resin film, a laminate or a printed circuit board, including but not limited to vinyl-containing polyphenylene ether resin, hydroxyl-containing polyphenylene ether resin, etc. In addition, for example, in one embodiment, the resin composition is also free from any one or more of cyanate ester resin, epoxy resin and phenolic resin.

For example, in one embodiment, the resin composition further comprises active ester, vinylbenzyl-dicyclopentadiene phenylene ether, bis(vinylbenzyl)ether, 1,2-bis(vinylphenyl)ethane, divinylbenzene, triallyl isocyanurate, triallyl cyanurate, 1,2,4-trivinyl cyclohexane, styrene, styrene maleic anhydride, acrylate, polyolefin, or a combination thereof. Unless otherwise specified, these components should be construed as including their modifications.

For example, in one embodiment, the resin composition further comprises styrene-butadiene-divinylbenzene terpolymer, hydrogenated styrene-butadiene-divinylbenzene terpolymer, styrene-butadiene-maleic anhydride terpolymer, hydrogenated styrene-butadiene-maleic anhydride terpolymer, vinyl-polybutadiene-urethane oligomer, styrene-butadiene copolymer, hydrogenated styrene-butadiene copolymer, styrene-isoprene copolymer, hydrogenated styrene-isoprene copolymer, maleic anhydride-butadiene copolymer, another polybutadiene, or a combination thereof.

For example, in one embodiment, the resin composition further comprises flame retardant, inorganic filler, curing accelerator, polymerization inhibitor, solvent, silane coupling agent, surfactant, coloring agent, toughening agent, core-shell rubber, or a combination thereof.

Another main object of the present disclosure is to provide an article made from the aforesaid resin composition, comprising a prepreg, a resin film, a laminate or a printed circuit board.

For example, in one embodiment, articles made from the resin composition disclosed herein have one, more or all of the following properties:
a dissipation factor as measured by reference to JIS C2565 at 10 GHz of less than or equal to 0.0025;
a water absorption ratio as measured by reference to IPC-TM-650 2.6.2.1a of less than or equal to 0.1%;
absence of tracking (e.g., dielectric breakdown) formed under a voltage of 600V as tested by reference to ASTM D3638; and
capable of passing a prepreg stickiness test.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

While some theories or mechanisms may be proposed herein, the present disclosure is not bound by any theories or mechanisms described regardless of whether they are right or wrong, as long as the embodiments can be implemented according to the present disclosure.

As used herein, “a,” “an” or any similar expression is employed to describe components and features of the present disclosure. This is done merely for convenience and to give a general sense of the scope of the present disclosure. Accordingly, this description should be read to include one or at least one and the singular also includes the plural unless it is obvious to mean otherwise.

As used herein, “or a combination thereof” means “or any combination thereof”, and “any” means “any one”, vice versa.

As used herein, the term “comprises,” “comprising,” “includes,” “including,” “encompass,” “has,” “having” or any other variant thereof is construed as an open-ended transitional phrase intended to cover a non-exclusive inclusion. For example, a composition or article of manufacture that comprises a list of elements is not necessarily limited to only those elements but may include other elements not expressly listed but inherent to such composition or article of manufacture. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “comprises,” “comprising,” “includes,” “including,” “has,” “having” or any other variant thereof, it is understood that close-ended transitional phrases such as “consisting of,” “composed by” and “remainder being” and partially open-ended transitional phrases such as “consisting essentially of,” “primarily consisting of,” “mainly consisting of,” “primarily containing,” “composed essentially of,” “essentially having,” etc. are also disclosed and included.

In this disclosure, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein. For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0. Unless otherwise defined, the aforesaid interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X₁, X₂ and X₃,” it is intended to disclose the situations of X is X₁ and X is X₁ and/or X₂ and/or X₃. In addition, when a Markush group or a list of items is used to describe examples or embodiments of the present disclosure, a skilled artisan will understand that any subgroup or any combination of the members or items in the Markush group or list may also be used to describe the present disclosure. Therefore, when X is described as being “selected from a group consisting of X₁, X₂ and X₃” and Y is described as being “selected from a group consisting of Y₁, Y₂ and Y₃,” the disclosure of any combination of X is X₁ and/or X₂ and/or X₃ and Y is Y₁ and/or Y₂ and/or Y₃.

Unless otherwise specified, according to the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property.

Unless otherwise specified, according to the present disclosure, a polymer refers to the product formed by monomer(s) via polymerization and usually comprises multiple aggregates of polymers respectively formed by multiple repeated simple structure units by covalent bonds; the monomer refers to the compound forming the polymer. A polymer may comprise a homopolymer, a copolymer, a prepolymer, etc., but not limited thereto. A prepolymer refers to a polymer having a lower molecular weight between the molecular weight of monomer and the molecular weight of final polymer. For example, according to the present disclosure, a prepolymer of diallyl compound and maleimide resin refers to a product with an intermediate molecular weight obtained by subjecting the diallyl compound and maleimide resin to a certain degree of polymerization, the intermediate molecular weight being greater than the molecular weight of the diallyl compound and maleimide resin before reaction but less than the molecular weight of the final product obtained from a complete reaction; in addition, the prepolymer contains a reactive functional group capable of participating further polymerization to obtain the final high molecular weight product which has been fully crosslinked or cured. The term “polymer” includes but is not limited to an oligomer. An oligomer refers to a polymer with 2-20, typically 2-5, repeating units. For example, the term “diene polymer” as used herein is construed as comprising diene homopolymer, diene copolymer, diene prepolymer and diene oligomer. For example, the term “(meth)acrylate polymer” as used herein is construed as comprising (meth)acrylate homopolymer, (meth)acrylate copolymer, (meth)acrylate prepolymer and (meth)acrylate oligomer.

Unless otherwise specified, the term “resin” of the present disclosure is a widely used common name of a synthetic polymer and is construed as comprising monomer and its combination, polymer and its combination or a combination of monomer and its polymer, but not limited thereto. For example, in the present disclosure, the term “maleimide resin” is construed to encompass a maleimide monomer, a maleimide polymer, a combination of maleimide monomers, a combination of maleimide polymers, and a combination of maleimide monomer(s) and maleimide polymer(s).

For example, in the present disclosure, the term “vinyl-containing” is construed to encompass the inclusion of a vinyl group, an allyl group, a (meth)acrylate group or a combination thereof.

Unless otherwise specified, according to the present disclosure, a modification comprises a product derived from a resin with its reactive functional group modified, a product derived from a prepolymerization reaction of a resin and other resins, a product derived from a crosslinking reaction of a resin and other resins, a product derived from homopolymerizing a resin, a product derived from copolymerizing a resin and other resins, etc.

The unsaturated bond described herein, unless otherwise specified, refers to a reactive unsaturated bond, such as but not limited to an unsaturated double bond with the potential of being crosslinked with other functional groups, such as an unsaturated carbon-carbon double bond with the potential of being crosslinked with other functional groups, but not limited thereto.

Unless otherwise specified, according to the present disclosure, when the term acrylate or acrylonitrile is expressed as (meth)acrylate or (meth)acrylonitrile, it is intended to comprise both situations of containing and not containing a methyl group; for example, poly(meth)acrylate is construed as including polyacrylate and polymethacrylate. For example, (meth)acrylonitrile is construed as including acrylonitrile and methacrylonitrile.

Unless otherwise specified, an alkyl group and an alkenyl group described herein are construed to encompass various isomers thereof. For example, a propyl group is construed to encompass n-propyl and iso-propyl.

It should be understood that all features disclosed herein may be combined in any way to constitute the solution of the present disclosure, as long as there is no conflict present in the combination of these features.

Unless otherwise specified, as used herein, part(s) by weight represents weight part(s) in any weight unit, such as but not limited to kilogram, gram, pound and so on. For example, 100 parts by weight of the polybutadiene may represent 100 kilograms of the polybutadiene or 100 pounds of the polybutadiene.

The following embodiments and examples are illustrative in nature and are not intended to limit the present disclosure and its application. In addition, the present disclosure is not bound by any theory described in the background and summary above or the following embodiments or examples. Unless otherwise specified, processes, reagents and conditions described in the examples are those known in the art.

Generally, the present disclosure provides a resin composition, comprising 100 parts by weight of a polybutadiene and 10 parts by weight to 40 parts by weight of a maleimide resin, wherein: the polybutadiene has a 1,2-vinyl content of greater than or equal to 85%; the polybutadiene has a lithium ion content of less than or equal to 100 ppm; and the resin composition is free from a polyphenylene ether resin.

As understood by those having ordinary skill in the art, polybutadiene is a homopolymer of butadiene. During the polymerization process, butadiene may be polymerized in the configuration of cis-1,4-addition, trans-1,4-addition or 1,2-addition. Therefore, monomer units of the end product polybutadiene may contain cis-1,4-addition unit, trans-1,4-addition unit or 1,2-addition unit. As the first main component of the resin composition disclosed herein, the polybutadiene according to the present disclosure refers to a polybutadiene in which the content of 1,2-addition units accounts for 85% or more of all units, i.e., the polybutadiene according to the present disclosure has a 1,2-vinyl content of greater than or equal to 85%. In one embodiment, for example, the polybutadiene has a 1,2-vinyl content of greater than or equal to 90%; in another embodiment, the polybutadiene has a 1,2-vinyl content of greater than or equal to 85% and less than or equal to 95%; in still another embodiment, the polybutadiene has a 1,2-vinyl content of greater than or equal to 90% and less than or equal to 95%, but not limited thereto.

In addition, as understood by those having ordinary skill in the art, the production of polybutadiene usually involves the use of a lithium-containing compound (e.g., n-butyllithium, BuLi) as the polymerization initiator; therefore, polybutadiene products contain residual lithium ions unless they are purified before sale. As the first main component of the resin composition disclosed herein, the polybutadiene according to the present disclosure refers to a polybutadiene in which the content of lithium ion is less than or equal to 100 ppm. In one embodiment, for example, the polybutadiene has a lithium ion content of between 1 ppm and 100 ppm or between 10 ppm and 100 ppm, but not limited thereto. In addition, unless otherwise specified, the lithium ion content may be measured by any conventional metal ion measurement instrument, such as but not limited to a mass spectrometer.

One of the main features of the resin composition according to the present disclosure is that the resin composition does not contain any polyphenylene ether resin. As used herein, the polyphenylene ether resin refers to any polyphenylene ether resins commonly used for preparing a prepreg, a resin film, a laminate or a printed circuit board, including but not limited to vinyl-containing polyphenylene ether resin, hydroxyl-containing polyphenylene ether resin, etc. In addition, for example, in one embodiment, the resin composition is also free from any one or more of cyanate ester resin, epoxy resin and phenolic resin.

In some embodiments, relative to 100 parts by weight of the polybutadiene, the resin composition according to the present disclosure comprises 10 parts by weight to 40 parts by weight of the maleimide resin, such as but not limited to 10 parts by weight, 20 parts by weight or 40 parts by weight of the maleimide resin.

As the second main component of the resin composition disclosed herein, the maleimide resin of the present disclosure comprises a monomer containing at least one maleimide group, its polymer, or a combination thereof. Unless otherwise specified, the maleimide resin used in the present disclosure is not particularly limited and may include any one or more maleimide resins useful for preparing a prepreg, a resin film, a laminate or a printed circuit board. In some embodiments, the maleimide resin may comprise 4,4′-diphenylmethane bismaleimide, polyphenylmethane maleimide (a.k.a. oligomer of phenylmethane maleimide), bisphenol A diphenyl ether bismaleimide, 3,3′-dimethyl-5,5′-diethyl-4,4′-diphenylmethane bismaleimide (a.k.a. bis-(3-ethyl-5-methyl-4-maleimidephenyl)methane), 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, vinyl benzyl maleimide (VBM), maleimide resin containing aliphatic long chain structure, prepolymer of diallyl compound and maleimide resin, prepolymer of diamine and maleimide resin, prepolymer of multi-functional amine and maleimide resin, prepolymer of acid phenol compound and maleimide resin, or a combination thereof. Unless otherwise specified, the maleimide resins described above should be construed as including the modifications thereof.

For example, the maleimide resin may include products such as BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 and BMI-7000H available from Daiwakasei Industry Co., Ltd., or products such as BMI-70 and BMI-80 available from K.I Chemical Industry Co., Ltd.

For example, the maleimide resin containing aliphatic long-chain structure may include products such as BMI-689, BMI-1400, BMI-1500, BMI-1700, BMI-2500, BMI-3000, BMI-5000 and BMI-6000 available from Designer Molecules Inc.

In one embodiment, for example, the resin composition may further optionally comprise active ester, vinylbenzyl-dicyclopentadiene phenylene ether, bis(vinylbenzyl) ether, 1,2-bis(vinylphenyl)ethane, divinylbenzene, triallyl isocyanurate, triallyl cyanurate, 1,2,4-trivinyl cyclohexane, styrene, styrene maleic anhydride, acrylate, polyolefin, or a combination thereof. Unless otherwise specified, these components should be construed as including their modifications. Unless otherwise specified, relative to 100 parts by weight of the polybutadiene, any component described above may range from 1 part by weight to 100 parts by weight, such as 1 part by weight to 50 parts by weight, and the ratio therebetween can be adjusted according to the need.

In one embodiment, for example, the active ester suitable for the present disclosure may be any active polyester resins known in the field to which this disclosure pertains, including but not limited to various commercially available active polyester resin products. Examples include, but not limited to, active polyester resin products HPC-8000 and HPC-8150 available from D.I.C. Corporation.

In one embodiment, for example, the vinylbenzyl-dicyclopentadiene phenylene ether suitable for the present disclosure is not particularly limited and may comprise but not limited to a structure shown below:

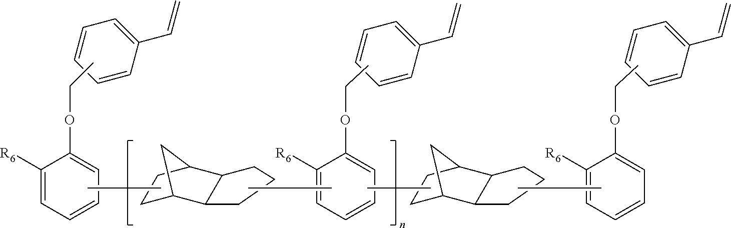

wherein each R₆ independently represents hydrogen, a C₁-C₂₀ straight chain alkyl group, a C₁-C₂₀ cycloalkyl group or a C₆-C₂₀ aryl group; and n is an integer of 1 to 10; preferably, R₆ is hydrogen or methyl group and n is an integer of 1 to 3.

The bis(vinylbenzyl)ether, 1,2-bis(vinylphenyl)ethane, divinylbenzene, triallyl isocyanurate, triallyl cyanurate, 1,2,4-trivinyl cyclohexane and styrene suitable for the present disclosure are not particularly limited and may comprise various commercially available products.

In one embodiment, for example, in the styrene maleic anhydride suitable for the present disclosure, the ratio of styrene (S) to maleic anhydride (MA) may be for example 1:1, 2:1, 3:1, 4:1, 6:1, 8:1 or 12:1, examples including styrene maleic anhydride resins such as SMA-1000, SMA-2000, SMA-3000, EF-30, EF-40, EF-60 and EF-80 available from Cray Valley, or styrene maleic anhydride copolymers such as C400, C500, C700 and C900 available from Polyscope, but not limited thereto.

In one embodiment, for example, the acrylate suitable for the present disclosure is not particularly limited, examples including the acrylate compound comprising two or more unsaturated bonds per molecule and various commercially available mono-functional acrylates.

In one embodiment, for example, the polyolefin suitable for the present disclosure includes but is not limited to any one or more commercial products, products synthesized by the Applicant or a combination thereof, such as but not limited to styrene-butadiene-divinylbenzene terpolymer, hydrogenated styrene-butadiene-divinylbenzene terpolymer, styrene-butadiene-maleic anhydride terpolymer, hydrogenated styrene-butadiene-maleic anhydride terpolymer, vinyl-polybutadiene-urethane oligomer, styrene-butadiene copolymer, hydrogenated styrene-butadiene copolymer, styrene-isoprene copolymer, hydrogenated styrene-isoprene copolymer, maleic anhydride-butadiene copolymer, another polybutadiene (i.e., a polybutadiene different from the one described above), or a combination thereof. For example, in one embodiment, relative to 100 parts by weight of the aforesaid polybutadiene, the amount of any polyolefin described above may be 10 parts by weight to 20 parts by weight.

Moreover, in addition to the aforesaid components, the resin composition disclosed herein may optionally further comprise flame retardant, inorganic filler, curing accelerator, polymerization inhibitor, solvent, silane coupling agent, surfactant, coloring agent, toughening agent, core-shell rubber, or a combination thereof.

In one embodiment, for example, the flame retardant suitable for the present disclosure may be any one or more flame retardants useful for preparing a prepreg, a resin film, a laminate or a printed circuit board, examples including but not limited to phosphorus-containing flame retardant, preferably comprising: ammonium polyphosphate, hydroquinone bis-(diphenylphosphate), bisphenol A bis-(diphenyl phosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenylphosphate) (RDXP, such as commercially available PX-200, PX-201, and PX-202), phosphazene (such as commercially available SPB-100, SPH-100, and SPV-100), melamine polyphosphate, 9,10-dihydro-9-oxa-10-phosphaphenanthrene-10-oxide (DOPO) and its derivatives (such as di-DOPO compounds) or resins, diphenylphosphine oxide (DPPO) and its derivatives (such as di-DPPO compounds) or resins, melamine cyanurate, tri-hydroxy ethyl isocyanurate, aluminium phosphinate (e.g., commercially available OP-930 and OP-935) or a combination thereof.

For example, the flame retardant may be a DPPO compound (e.g., di-DPPO compound), a DOPO compound (e.g., di-DOPO compound), a DOPO resin (e.g., DOPO-HQ, DOPO-NQ, DOPO-PN, and DOPO-BPN), and a DOPO-containing epoxy resin, wherein DOPO-PN is a DOPO-containing phenol novolac resin, and DOPO-BPN may be a DOPO-containing bisphenol novolac resin, such as DOPO-BPAN (DOPO-bisphenol A novolac), DOPO-BPFN (DOPO-bisphenol F novolac) and DOPO-BPSN (DOPO-bisphenol S novolac).

Unless otherwise specified, relative to 100 parts by weight of the polybutadiene used in the present disclosure, the amount of the aforesaid flame retardant is not particularly limited and may be 1 part by weight to 100 parts by weight, such as 1 part by weight to 50 parts by weight or 30 parts by weight to 50 parts by weight.

The inorganic filler suitable for the present disclosure may be any one or more inorganic fillers suitable for preparing a prepreg, a resin film, a laminate or a printed circuit board, examples including but not limited to silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride and calcined kaolin. Moreover, the inorganic filler can be spherical, fibrous, plate-like, particulate, sheet-like or whisker-like and can be optionally pretreated by a silane coupling agent.

Unless otherwise specified, relative to 100 parts by weight of the polybutadiene used in the present disclosure, the amount of the aforesaid inorganic filler is not particularly limited and may be 10 parts by weight to 400 parts by weight, such as 50, 100, 150, 200, 250, 300 or 350 parts by weight.

The curing accelerator suitable for the present disclosure may comprise a catalyst, such as a Lewis base or a Lewis acid. The Lewis base may comprise imidazole, boron trifluoride-amine complex, ethyltriphenyl phosphonium chloride, 2-methylimidazole (2MI), 2-phenyl-1H-imidazole (2PZ), 2-ethyl-4-methylimidazole (2E4MI), triphenylphosphine (TPP) and 4-dimethylaminopyridine (DMAP) or a combination thereof. The Lewis acid may comprise metal salt compounds, such as those of manganese, iron, cobalt, nickel, copper and zinc, such as zinc octanoate or cobalt octanoate. The curing accelerator encompasses curing initiator such as a peroxide capable of producing free radicals, and examples of the curing initiator may comprise, but not limited to: dibenzoyl peroxide (BPO), dicumyl peroxide, 2,5-dimethyl-2,5-di(t-butylperoxy)hexane, 2,5-dimethyl-2,5-di(t-butylperoxy)-3-hexyne (25B), di-t-butyl peroxide, di(t-butylperoxyisopropyl)benzene, di(t-butylperoxy)phthalate, di(t-butylperoxy)isophthalate, t-butyl peroxybenzoate, 2,2-di(t-butylperoxy)butane, 2,2-di(t-butylperoxy)octane, 2,5-dimethyl-2,5-di(benzoyl peroxy)hexane, lauroyl peroxide, t-hexyl peroxypivalate, dibutylperoxy isopropylbenzene, bis(4-t-butylcyclohexyl) peroxydicarbonate or a combination thereof.

Unless otherwise specified, the amount of curing accelerator used in the present disclosure may be adjusted according to the need; for example, but not limited thereto, relative to 100 parts by weight of the polybutadiene, the amount of curing accelerator may be 0.01 to 20 parts by weight and preferably 5 to 20 parts by weight.

As used herein, the polymerization inhibitor is used to inhibit the polymerization reaction, and examples thereof are not particularly limited, which may include various molecule type polymerization inhibitors, mediated radical type polymerization inhibitors or a combination thereof known in the field to which this disclosure pertains. For example, molecule type polymerization inhibitors suitable for the present disclosure include but are not limited to phenols, quinones, arylamines, arene nitro compounds, sulfur-containing compounds, chlorides of metal with variable valency or a combination thereof. More specifically, molecule type polymerization inhibitors suitable for the present disclosure include but are not limited to phenol, hydroquinone, 4-tert-butylcatechol, benzoquinone, chloroquinone, 1,4-naphthoquinone, trimethylquinone, aniline, nitrobenzene, Na₂S, FeCl₃, CuCl₂ or a combination thereof. For example, mediated radical type polymerization inhibitors suitable for the present disclosure include but are not limited to 1,1-diphenyl-2-picrylhydrazyl radical (DPPH), triphenylmethyl radical or a combination thereof.

Unless otherwise specified, the amount of polymerization inhibitor used in the present disclosure may be adjusted according to the need; for example, but not limited thereto, relative to 100 parts by weight of the polybutadiene, the amount of polymerization inhibitor may be 0.01 to 5 parts by weight and preferably 0.1 to 2 parts by weight.

The purpose of adding solvent according to the present disclosure is to dissolve the components in the resin composition so as to change the solid content of the resin composition and to adjust the viscosity of the resin composition. For example, the solvent may comprise, but not limited to, methanol, ethanol, ethylene glycol monomethyl ether, acetone, butanone (i.e., methyl ethyl ketone), methyl isobutyl ketone, cyclohexanone, toluene, xylene, methoxyethyl acetate, ethoxyethyl acetate, propoxyethyl acetate, ethyl acetate, propylene glycol methyl ether, dimethyl formamide, dimethyl acetamide, N-methyl-pyrrolidone, or a mixture thereof.

The silane coupling agent suitable for the present disclosure may comprise silane (such as but not limited to siloxane), which may be further categorized according to the functional groups into amino silane, epoxide silane, vinyl silane, ester silane, hydroxyl silane, isocyanate silane, methacryloxy silane and acryloxy silane.

The purpose of surfactant used herein is to ensure uniform distribution of the inorganic filler in the resin composition.

The coloring agent suitable for the present disclosure may comprise, but not limited to, dye or pigment.

The purpose of toughening agent used herein is to improve the toughness of the resin composition. The toughening agent may comprise, but not limited to, carboxyl-terminated butadiene acrylonitrile rubber (CTBN rubber).

The resin compositions of various embodiments of the present disclosure may be processed by various methods into different articles, including but not limited to a prepreg, a resin film, a laminate or a printed circuit board.

For example, the resin compositions of various embodiments may be used to make prepregs.

In one embodiment, the prepreg disclosed herein has a reinforcement material and a layered structure formed thereon, wherein the layered structure is made by heating the resin composition at high temperature to a semi-cured state (B-stage). Suitable baking temperature for making the prepreg may be for example 140° C. to 170° C. The reinforcement material may be any one of a fiber material, woven fabric, and non-woven fabric, and the woven fabric preferably comprises fiberglass fabrics. Types of fiberglass fabrics are not particularly limited and may be any commercial fiberglass fabric useful for various printed circuit boards, such as E-glass fiber fabric, D-glass fiber fabric, S-glass fiber fabric, T-glass fiber fabric, L-glass fiber fabric or Q-glass fiber fabric, wherein the fiber may comprise yarns and rovings, in spread form or standard form. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can be optionally pre-treated by a silane coupling agent. The prepreg may be further heated and cured to the C-stage to form an insulation layer.

In one embodiment, by well mixing the resin composition to form a varnish, loading the varnish into an impregnation tank, impregnating a fiberglass fabric into the impregnation tank to adhere the resin composition onto the fiberglass fabric, and proceeding with heating and baking at a proper temperature to a semi-cured state, a prepreg may be obtained.

For example, the article made from the resin composition disclosed herein may be a resin film which is prepared by heating and baking the resin composition to the semi-cured state. For example, by selectively coating the resin composition on a liquid crystal polymer film, a polyethylene terephthalate film (PET film) or a polyimide film, followed by heating and baking at a proper temperature to a semi-cured state, a resin film may be obtained. For example, the resin composition from each embodiment may be coated on a copper foil to uniformly adhere the resin composition thereon, followed by heating and baking at a proper temperature to a semi-cured state to obtain the resin film.

For example, the resin composition of the present disclosure may be made into a laminate, which comprises at least two metal foils and an insulation layer disposed between the metal foils, wherein the insulation layer is made by curing the resin composition at high temperature and high pressure to the C-stage, a suitable curing temperature being for example between 190° C. and 240° C. and preferably between 190° C. and 230° C., a suitable curing time being 60 to 180 minutes and preferably 60 to 150 minutes, and a suitable pressure being for example between 400 and 800 psi and preferably between 600 and 700 psi. The insulation layer may be obtained by curing the aforesaid prepreg or resin film. The metal foil may contain copper, aluminum, nickel, platinum, silver, gold or alloy thereof, such as a copper foil. In a preferred embodiment, the laminate is a copper-clad laminate.

In one embodiment, the laminate may be further processed by trace formation processes to obtain a printed circuit board.

For example, in one embodiment of making a printed circuit board, a double-sided copper-clad laminate (such as product EM-891, available from Elite Material Co., Ltd.) with a thickness of 28 mil and having 1 ounce (oz) HVLP (hyper very low profile) copper foils may be used and subjected to drilling and then electroplating, so as to form electrical conduction between the upper layer copper foil and the bottom layer copper foil. Then the upper layer copper foil and the bottom layer copper foil are etched to form inner layer circuits. Then brown oxidation and roughening were performed on the inner layer circuits to form uneven structures on the surface to increase roughness. Next, a vacuum lamination apparatus is used to laminate the assembly of a copper foil, the prepreg, the inner layer circuit board, the prepreg and a copper foil stacked in said order by heating at 190° C. to 240° C. for 60 to 180 minutes to cure the insulation material of the prepregs. Next, black oxidation, drilling, copper plating and other known circuit board processes are performed on the outmost copper foils so as to obtain the printed circuit board.

In one embodiment, the resin composition disclosed herein may achieve improvement in one or more of the following properties: dissipation factor, water absorption ratio, tracking property and prepreg stickiness.

For example, articles made from the resin compositions according to the present disclosure may achieve one, more or all of the following properties:
a dissipation factor as measured by reference to JIS C2565 at 10 GHz of less than or equal to 0.0025;
a water absorption ratio as measured by reference to IPC-TM-650 2.6.2.1a of less than or equal to 0.1%;
absence of tracking formed under a voltage of 600V as tested by reference to ASTM D3638; and
capable of passing a prepreg stickiness test.

Raw materials below were used to prepare the resin compositions of various Examples and Comparative Examples of the present disclosure according to the amount listed in Table 1 to Table 4 and further fabricated to prepare test samples.

Chemical reagents and item numbers used in Examples and Comparative Examples disclosed herein are listed below:
A-1: polybutadiene having a 1,2-vinyl content of greater than or equal to 85% and a lithium ion content of less than or equal to 100 ppm, product name B-1000, available from Nippon Soda Co., Ltd.
A-2: polybutadiene having a 1,2-vinyl content of greater than or equal to 90% and a lithium ion content of less than or equal to 100 ppm, product name B-3000, available from Nippon Soda Co., Ltd.
A-3: polybutadiene having a 1,2-vinyl content of greater than or equal to 90% and a lithium ion content of greater than 300 ppm, product name Ricon 154, available from Cray Valley.
A-4: polybutadiene having a 1,2-vinyl content of 70%, product name Ricon 150, available from Cray Valley.
A-5: polybutadiene having a 1,2-vinyl content of 28%, product name Ricon 131, available from Cray Valley.
B-1: 3,3′-dimethyl-5,5′-diethyl-4,4′-diphenylmethane bismaleimide, product name BMI-5100, available from Daiwakasei Industry Co., Ltd.
B-2: bisphenol A diphenyl ether bismaleimide, product name BMI-4000, available from Daiwakasei Industry Co., Ltd.
B-3: polyphenylmethane maleimide, product name BMI-2300, available from Daiwakasei Industry Co., Ltd.
B-4: maleimide resin containing aliphatic long chain structure, product name BMI-3000, available from Designer Molecules Inc.
H-1: vinylbenzyl-terminated polyphenylene ether resin, product name OPE-2st 2200, available from Mitsubishi Gas Chemical Co., Inc.
H-2: methacrylate-terminated polyphenylene ether resin, product name SA9000, available from Sabic.
H-3: hydroxyl-terminated polyphenylene ether resin, product name SA120, available from Sabic.
A-6: styrene-butadiene copolymer, having a 1,2-vinyl content of 70%, product name Ricon 100, available from Cray Valley.
A-7: styrene-butadiene copolymer, having a 1,2-vinyl content of 30%, product name Ricon 184, available from Cray Valley.
A-8: styrene-butadiene-divinylbenzene terpolymer, product name Ricon 257, available from Cray Valley.
A-9: styrene-butadiene copolymer, product name D-1118, available from Kraton Polymers.
A-10: hydrogenated styrene-butadiene copolymer, product name H1052, available from Asahi Kasei Corp.
C-1: spherical silica, product name SC2500-SXJ, available from Admatechs.
D-1: curing accelerator, dicumyl peroxide, commercially available.
E-1: polymerization inhibitor, 4,4′-butylidenebis(6-t-butyl-3-methylphenol), commercially available.
F-1: flame retardant, product name 8010, available from Albemarle Corporation.
F-2: flame retardant, product name BT-93, available from Albemarle Corporation.
G-1: solvent, which is a mixture of toluene and methyl ethyl ketone (weight ratio of 50:50), prepared by Applicant. “PA” in the Tables represents a “proper amount”, which is the amount of solvent sufficient to dissolve all of the maleimide resin, curing accelerator and polymerization inhibitor.

Compositions and test results of resin compositions of Examples and Comparative Examples are listed below (in part by weight):

TABLE 1
Resin compositions of Examples (in part by weight) and test results

| | Item | | | | | | | |
|---|---|---|---|---|---|---|---|---|
| Component | number | E1 | E2 | E3 | E4 | E5 | E6 | E7 |
| polybutadiene | A-1 | 100 | 100 | 100 | 50 | 70 | 100 | 60 |
| | A-2 | | | | 50 | 30 | | 40 |
| | A-3 | | | | | | | |
| | A-4 | | | | | | | |
| | A-5 | | | | | | | |
| maleimide resin | B-1 | 20 | 10 | 40 | 20 | 16 | 24 | 8 |
| | B-2 | | | | | 4 | | 6 |
| | B-3 | | | | | | | 4 |
| | B-4 | | | | | | | 2 |
| polyphenylene | H-1 | | | | | | | |
| ether resin | H-2 | | | | | | | |
| | H-3 | | | | | | | |
| polyolefin | A-6 | | | | | | 10 | 6 |
| | A-7 | | | | | | | 4 |
| | A-8 | | | | | | 4 | 4 |
| | A-9 | | | | | 10 | | 6 |
| | A-10 | | | | | | | |
| inorganic filler | C-1 | 300 | 300 | 300 | 300 | 300 | 200 | 400 |
| curing accelerator | D-1 | 6 | 6 | 6 | 6 | 6 | 6 | 20 |
| polymerization | E-1 | | | | | | 0.4 | 0.5 |
| inhibitor | | | | | | | | |
| flame retardant | F-1 | 30 | 30 | 30 | 30 | 30 | 30 | 30 |
| | F-2 | 10 | 10 | 10 | 10 | 10 | 10 | 10 |
| solvent | G-1 | PA | PA | PA | PA | PA | PA | PA |
| Test item | Unit | E1 | E2 | E3 | E4 | E5 | E6 | E7 |
| Df | none | ≤0.0025 | ≤0.0025 | ≤0.0025 | ≤0.0025 | ≤0.0025 | ≤0.0025 | ≤0.0025 |
| water absorption | % | ≤0.1 | ≤0.1 | ≤0.1 | ≤0.1 | ≤0.1 | ≤0.1 | ≤0.1 |
| ratio | | | | | | | | |
| CTI | none | pass | pass | pass | pass | pass | pass | pass |
| stickiness | none | pass | pass | pass | pass | pass | pass | pass |

TABLE 2
Resin compositions of Comparative Examples (in part by weight) and test results

| | Item | | | | | | | |
|---|---|---|---|---|---|---|---|---|
| Component | number | C1 | C2 | C3 | C4 | C5 | C6 | C7 |
| polybutadiene | A-1 | 100 | 100 | 100 | 100 | 100 | 100 | 100 |
| | A-2 | | | | | | | |
| | A-3 | | | | | | | |
| | A-4 | | | | | | | |
| | A-5 | | | | | | | |
| maleimide resin | B-1 | 4 | 60 | | | | | 20 |
| | B-2 | | | | | | | |
| | B-3 | | | | | | | |
| | B-4 | | | | | | | |
| polyphenylene | H-1 | | | | | 20 | 10 | 20 |
| ether resin | H-2 | | | | | | 10 | |
| | H-3 | | | | | | | |
| polyolefin | A-6 | | | | | | | |
| | A-7 | | | | | | | |
| | A-8 | | | | | | | |
| | A-9 | | | | 20 | | | |
| | A-10 | | | | 10 | | | |
| inorganic filler | C-1 | 300 | 300 | 300 | 300 | 300 | 300 | 300 |
| curing accelerator | D-1 | 6 | 6 | 6 | 6 | 6 | 6 | 6 |
| polymerization | E-1 | | | | | | | |
| inhibitor | | | | | | | | |
| flame retardant | F-1 | 30 | 30 | 30 | 30 | 30 | 30 | 30 |
| | F-2 | 10 | 10 | 10 | 10 | 10 | 10 | 10 |
| solvent | G-1 | PA | PA | PA | PA | PA | PA | PA |
| Test item | Unit | C1 | C2 | C3 | C4 | C5 | C6 | C7 |
| Df | none | ≤0.0025 | ≤0.0025 | ≤0.0025 | ≤0.0025 | ≤0.0025 | ≤0.0025 | ≤0.0025 |
| water absorption | % | ≤0.1 | ≤0.2 | ≤0.1 | ≤0.1 | ≤0.1 | ≤0.1 | ≤0.1 |
| ratio | | | | | | | | |
| CTI | none | pass | fail | pass | pass | fail | fail | fail |
| stickiness | none | fail | pass | fail | fail | fail | fail | pass |

TABLE 3
Resin compositions of Comparative Examples (in part by weight) and test results

| | Item | | | | | | | |
|---|---|---|---|---|---|---|---|---|
| Component | number | C8 | C9 | C10 | C11 | C12 | C13 | C14 |
| polybutadiene | A-1 | 100 | 100 | | | | | |
| | A-2 | | | | | | | |
| | A-3 | | | | | 100 | | |
| | A-4 | | | 100 | 100 | | | |
| | A-5 | | | | | | | |
| maleimide resin | B-1 | 20 | 20 | | 20 | 20 | | 20 |
| | B-2 | | | | | | | |
| | B-3 | | | | | | | |
| | B-4 | | | | | | | |
| polyphenylene | H-1 | 10 | | | | | | |
| ether resin | H-2 | 10 | | | | | | |
| | H-3 | | 20 | | | | | |
| polyolefin | A-6 | | | | | | 100 | 80 |
| | A-7 | | | | | | | 20 |
| | A-8 | | | | | | | |
| | A-9 | | | | | | | |
| | A-10 | | | | | | | |
| inorganic filler | C-1 | 300 | 300 | 300 | 300 | 300 | 300 | 300 |
| curing accelerator | D-1 | 6 | 6 | 6 | 6 | 6 | 6 | 6 |
| polymerization | E-1 | | | | | | | |
| inhibitor | | | | | | | | |
| flame retardant | F-1 | 30 | 30 | 30 | 30 | 30 | 30 | 30 |
| | F-2 | 10 | 10 | 10 | 10 | 10 | 10 | 10 |
| solvent | G-1 | PA | PA | PA | PA | PA | PA | PA |
| Test item | Unit | C8 | C9 | C10 | C11 | C12 | C13 | C14 |
| Df | none | ≤0.0025 | ≤0.0030 | ≤0.0025 | ≤0.0025 | ≤0.0025 | ≤0.0025 | ≤0.0025 |
| water absorption | % | ≤0.1 | ≤0.1 | ≤0.1 | ≤0.1 | ≤0.1 | ≤0.1 | ≤0.2 |
| ratio | | | | | | | | |
| CTI | none | fail | fail | fail | fail | fail | fail | fail |
| stickiness | none | pass | fail | fail | pass | pass | fail | fail |

TABLE 4
Resin compositions of Comparative Examples (in part by weight) and test results

| | Item | | | | | |
|---|---|---|---|---|---|---|
| Component | number | C15 | C16 | C17 | C18 | C19 |
| polybutadiene | A-1 | | | | 20 | 40 |
| | A-2 | | | | | |
| | A-3 | | | | | |
| | A-4 | | 80 | | | |
| | A-5 | | 20 | | | |
| maleimide resin | B-1 | 20 | | 20 | 100 | 20 |
| | B-2 | | | | | |
| | B-3 | | | | | |
| | B-4 | | | | | |
| polyphenylene | H-1 | | | 100 | | |
| ether resin | H-2 | | | | | |
| | H-3 | | | | | |
| polyolefin | A-6 | | | 10 | | |
| | A-7 | | | 10 | | |
| | A-8 | | | | | |
| | A-9 | | 20 | 10 | | |
| | A-10 | 100 | 10 | 10 | | |
| inorganic filler | C-1 | 300 | 300 | 300 | 300 | 200 |
| curing accelerator | D-1 | 6 | 6 | 6 | 6 | 6 |
| polymerization | E-1 | | | | | |
| inhibitor | | | | | | |
| flame retardant | F-1 | 30 | 30 | 30 | 30 | 30 |
| | F-2 | 10 | 10 | 10 | 10 | 10 |
| solvent | G-1 | PA | PA | PA | PA | PA |
| Test item | Unit | C15 | C16 | C17 | C18 | C19 |
| Df | none | ≤0.0025 | ≤0.0025 | ≤0.0025 | ≤0.0030 | ≤0.0030 |
| water absorption | % | ≤0.1 | ≤0.1 | ≤0.2 | ≤0.2 | ≤0.2 |
| ratio | | | | | | |
| CTI | none | fail | fail | fail | fail | fail |
| stickiness | none | pass | fail | pass | pass | pass |

Samples (specimens) for the properties measured above were prepared as described below and tested and analyzed under specified conditions below.
1. Prepreg: Resin composition from each Example (Table 1) or each Comparative Example (Tables 2-4) was individually well-mixed to form a varnish, which was then loaded to an impregnation tank; a fiberglass fabric (e.g., 1080 L-glass fiber fabric, available from Asahi) was impregnated into the impregnation tank to adhere the resin composition onto the fiberglass fabric, followed by heating at 140° C. to 160° C. to a semi-cured state (B-stage) to obtain a prepreg with a resin content of about 70%.
2. Copper-free laminate (2-ply, formed by lamination of two prepregs): Two 18 μm HVLP (hyper very low profile) copper foils and two prepregs obtained from 1080 L-glass fiber fabrics impregnated with each Example or Comparative Example were prepared and stacked in the order of one copper foil, two prepregs and one copper foil, followed by lamination and curing under vacuum at 600 psi and 230° C. for 1 hour to form a copper-containing laminate (2-ply, formed by lamination of two prepregs). Next, each copper-containing laminate was etched to remove the copper foils on both sides to obtain a copper-free laminate (2-ply) which is formed by laminating two prepregs and has a resin content of about 70%.
3. Copper-free laminate (8-ply, formed by lamination of eight prepregs): Two 18 μm HVLP (hyper very low profile) copper foils and eight prepregs obtained from 1080 L-glass fiber fabrics impregnated with each Example or Comparative Example were prepared and stacked in the order of one copper foil, eight prepregs and one copper foil, followed by lamination and curing under vacuum at 600 psi and 230° C. for 1 hour to form a copper-containing laminate (8-ply, formed by lamination of eight prepregs). Next, each copper-containing laminate was etched to remove the copper foils on both sides to obtain a copper-free laminate (8-ply) which has a resin content of about 70%.
4. Copper-free laminate (18-ply, formed by lamination of eighteen prepregs): Two 18 μm HVLP (hyper very low profile) copper foils and eighteen prepregs obtained from 1080 L-glass fiber fabrics impregnated with each Example or Comparative Example were prepared and stacked in the order of one copper foil, eighteen prepregs and one copper foil, followed by lamination and curing under vacuum at 600 psi and 230° C. for 1 hour to form a copper-containing laminate (18-ply, formed by lamination of eighteen prepregs). Next, each copper-containing laminate was etched to remove the copper foils on both sides to obtain a copper-free laminate (18-ply) which has a resin content of about 70%.

For each sample, test items and test methods are described below.

Dissipation Factor (Df)

In the dissipation factor measurement, the copper-free laminate (2-ply) was tested by using a microwave dielectrometer available from AET Corp. by reference to JIS C2565 “Measuring methods for ferrite cores for microwave device” at 10 GHz for analyzing each sample. Lower dissipation factor represents better dielectric properties of the sample. Under a 10 GHz frequency, for a Df value of less than 0.0030, a difference in Df of less than 0.0002 represents no substantial difference in dissipation factor of different laminates, and a difference in Df of greater than or equal to 0.0002 represents a substantial difference in dissipation factor of different laminates. Df value has no unit. For example, articles made from the resin composition disclosed herein have a dissipation factor as measured by reference to JIS C2565 at 10 GHz of less than or equal to 0.0020, such as between 0.0015 and 0.0020.

Water Absorption Ratio

In the water absorption ratio test, by reference to IPC-TM-650 2.6.2.1a, a 2 inch*2 inch copper-free laminate sample obtained by laminating eight prepregs was placed in a 105±10° C. oven and baked for 1 hour, then cooled at room temperature of about 25° C. for 10 minutes and weighed to give a weight value W1 representing the weight of the copper-free laminate; then the copper-free laminate sample was immersed and soaked in pure water at room temperature for 24 hours, then withdrawn from the pure water and wiped to remove residual water on the surface, and the sample was weighed again to give a weight value W2 representing the weight of the copper-free laminate after water absorption. The water absorption ratio W was calculated as follow: W(%)=((W2−W1)/W1)×100%. The unit of water absorption ratio is %.

For example, articles made from the resin composition disclosed herein have a water absorption ratio as measured by reference to IPC-TM-650 2.6.2.1a of less than or equal to 0.1%, such as between 0.10% and 0.05%.

Comparative Tracking Index (CTI)

The aforesaid copper-free laminate sample (obtained by laminating eighteen prepregs) with a size of 100 mm*100 mm*3 mm was tested by reference to ASTM D3638. During the test, a 100V voltage was applied to the sample on the tester, followed by addition of one drop of 0.1 wt % ammonium chloride aqueous solution every 30 seconds until tracking was formed, and the total number of drops added was recorded. If tracking was not formed after the addition of 50 drops, the voltage was increased from 50V to 150V to test the tolerable voltage value of the sample ranging from 100V to 600V with a voltage increment of 50V per increase. The unit used in the comparative tracking index test is voltage (abbreviated as “V”). A difference in voltage of greater than or equal to 5V represents a substantial difference. If tracking was not formed at a voltage of 600V after the addition of 50 drops, a designation of “pass” is given. If tracking was formed at a voltage of 600V or less, a designation of “fail” is given.

Stickiness (Degree of Resin Loss from Prepreg Surface)

The prepreg was cut to a sheet size of 21 cm×30 cm. Ten sheets were aligned and stacked and placed into an aluminum foil package bag and were subject to vacuum packaging. After that, the package bag was placed to a constant temperature cabinet at 30° C. for 72 hours, and then the 10 sheets of prepreg were removed from the package bag and peeled off one by one. During the peeling process, the 10 sheets of prepreg were first erected as a whole, and then the outmost prepreg was attached with a 10 gram weight at any upper corner such that the outmost prepreg was peeled off from the other 9 prepregs due to the existence of gravity. The duration from the weight has been attached to the outmost prepreg has been completely peeled off (by visual inspection) was recorded. A set of five measurements were recorded, and the average thereof was calculated. If the average of the five measurements is less than or equal to 10 seconds, a designation of “pass” is given. Otherwise, if the average of the five measurements is greater than or equal to 10 seconds, a designation of “fail” is given.

The following observations can be made according to the test results above.

Examples E1 to E7 use a resin composition containing both 100 parts by weight of the polybutadiene (1,2-vinyl content of greater than or equal to 85% and lithium ion content of less than or equal to 100 ppm) of the present disclosure and 10 parts by weight to 40 parts by weight of the maleimide resin and are all capable of passing the comparative tracking index test and the prepreg stickiness test at the same time.

In contrast to Examples E1 to E7, Comparative Examples C1 and C2, which contain the maleimide resin in an amount outside the range of 10 parts by weight to 40 parts by weight, and Comparative Examples C3 and C4, which do not contain the maleimide resin, all fail to pass the comparative tracking index test and the prepreg stickiness test at the same time, and Comparative Example C2 undesirably has high water absorption ratio problem.

In contrast to Examples E1 to E7, Comparative Examples C5 and C6, which contain 20 parts by weight a polyphenylene ether resin instead of the maleimide resin, and Comparative Examples C7 to C9, which contain both 20 parts by weight of the maleimide resin and 20 parts by weight of a polyphenylene ether resin, all fail to pass the comparative tracking index test and the prepreg stickiness test at the same time.

In contrast to Examples E1 to E7, Comparative Examples C10 and C11, which contain 100 parts by weight of a polybutadiene having a 1,2-vinyl content of less than 85%, and Comparative Example C12, which contains 100 parts by weight of a polybutadiene having a 1,2-vinyl content of greater than or equal to 85% but a lithium ion content of greater than 300 ppm, all fail to pass the comparative tracking index test and the prepreg stickiness test at the same time.

In contrast to Examples E1 to E7, Comparative Examples C13 to C15, which contain 100 parts by weight of other polyolefin (e.g., styrene-butadiene copolymer or hydrogenated styrene-butadiene copolymer), all fail to pass the comparative tracking index test and the prepreg stickiness test at the same time, and Comparative Example C14 undesirably has high water absorption ratio problem.

In contrast to Examples E1 to E7, Comparative Example C16, which contains 100 parts by weight of a polybutadiene having a 1,2-vinyl content of less than 85% and contains other polyolefin but is free from the maleimide resin, fails to pass the comparative tracking index test and the prepreg stickiness test at the same time.

In contrast to Examples E1 to E7, Comparative Example C17, which contains 20 parts by weight of the maleimide resin, 40 parts by weight of other polyolefin and 100 parts by weight of a polyphenylene ether resin, fails to pass the comparative tracking index test and the prepreg stickiness test at the same time.

In addition, in contrast to Examples E1 to E7, it can be observed from Comparative Examples C18 and C19 that even if the resin composition contains the polybutadiene of the present disclosure (1,2-vinyl content of greater than or equal to 85% and lithium ion content of less than or equal to 100 ppm) and the maleimide resin and is free from a polyphenylene ether resin, if the amount or ratio of the polybutadiene and the maleimide resin in the resin composition fall outside the range specified in the present disclosure, the resin composition will still fail to pass the comparative tracking index test and the prepreg stickiness test at the same time.

In general, the resin composition of the present disclosure can pass the comparative tracking index test and the prepreg stickiness test at the same time. Furthermore, articles made from the resin composition disclosed herein have one, more or all of the following properties: a dissipation factor as measured by reference to JIS C2565 at 10 GHz of less than or equal to 0.0025; a water absorption ratio as measured by reference to IPC-TM-650 2.6.2.1a of less than or equal to 0.1%; absence of tracking formed under a voltage of 600V as tested by reference to ASTM D3638; and passing the prepreg stickiness test.

The above detailed description is merely illustrative in nature and is not intended to limit the embodiments of the subject matter or the application and use of such embodiments. As used herein, the term “exemplary” means “serving as an example, instance, or illustration.” Any implementation described herein as exemplary is not necessarily to be construed as preferred or advantageous over other implementations.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made in the function and arrangement of elements without departing from the scope defined by the claims, which include known equivalents and foreseeable equivalents at the time of filing this patent application.

What is claimed is:

1. A resin composition, comprising 100 parts by weight of a polybutadiene and 10 parts by weight to 40 parts by weight of a maleimide resin, wherein:
the polybutadiene has a 1,2-vinyl content of greater than or equal to 85%;
the polybutadiene has a lithium ion content of less than or equal to 100 ppm; and
the resin composition is free from a polyphenylene ether resin.

2. The resin composition of claim 1, wherein the maleimide resin comprises 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylyl maleimide, N-phenyl maleimide, vinyl benzyl maleimide, maleimide resin containing aliphatic long chain structure, prepolymer of diallyl compound and maleimide resin, prepolymer of diamine and maleimide resin, prepolymer of multi-functional amine and maleimide resin, prepolymer of acid phenol compound and maleimide resin, or a combination thereof.

3. The resin composition of claim 1, further comprising active ester, vinylbenzyl-dicyclopentadiene phenylene ether, bis(vinylbenzyl)ether, 1,2-bis (vinylphenyl)ethane, divinylbenzene, triallyl isocyanurate, triallyl cyanurate, 1,2,4-trivinyl cyclohexane, styrene, styrene maleic anhydride, acrylate, polyolefin, or a combination thereof.

4. The resin composition of claim 3, wherein the polyolefin comprises styrene-butadiene-divinylbenzene terpolymer, hydrogenated styrene-butadiene-divinylbenzene terpolymer, styrene-butadiene-maleic anhydride terpolymer, hydrogenated styrene-butadiene-maleic anhydride terpolymer, vinyl-polybutadiene-urethane oligomer, styrene-butadiene copolymer, hydrogenated styrene-butadiene copolymer, styrene-isoprene copolymer, hydrogenated styrene-isoprene copolymer, maleic anhydride-butadiene copolymer, another polybutadiene, or a combination thereof.

5. The resin composition of claim 1, further comprising flame retardant, inorganic filler, curing accelerator, polymerization inhibitor, solvent, silane coupling agent, surfactant, coloring agent, toughening agent, core-shell rubber, or a combination thereof.

6. An article made from the resin composition of claim 1, comprising a prepreg, a resin film, a laminate or a printed circuit board.

7. The article of claim 6, characterized by not forming tracking under a voltage of 600V as tested by reference to ASTM D3638.

8. The article of claim 6, characterized by passing a prepreg stickiness test.
